(19) United States
(12) Patent Application Publication
(10) Pub. No.: US 2011/0061910 A1
(43) Pub. Date: Mar. 17, 2011

(54) MULTI-LAYER CERAMIC CIRCUIT BOARD, METHOD OF MANUFACTURING THE SAME, AND ELECTRIC DEVICE MODULE USING THE SAME

(75) Inventors: Je Hong SUNG, Gyunggi-do (KR); Yun Hee CHO, Gyunggi-do (KR); Kwang Jae OH, Gyunggi-do (KR)

(73) Assignee: SAMSUNG ELECTRO-MECHANICS CO., LTD.

(21) Appl. No.: 12/648,201

(22) Filed: Dec. 28, 2009

(30) Foreign Application Priority Data
Sep. 16, 2009 (KR) 10-2009-0087724

(51) Int. Cl. H05K 1/00; H05K 3/00

(52) U.S. Cl. 174/258; 29/829; 29/846; 29/852

(57) ABSTRACT

There is provided a multi-layer ceramic circuit board. The multi-layer ceramic circuit board according to an aspect of the invention may include: a ceramic body having a plurality of ceramic green sheets stacked upon one another and an interlayer circuit having conductive vias and conductive patterns separately provided in the plurality of ceramic green sheets; a bump receiving portion provided in at least one surface ceramic green sheet adjacent to a surface of the plurality of ceramic green sheets, and having side walls inclined upward; and a bonding pad provided on the inclined side walls and a bottom surface of the bump receiving portion, and connected to the interlayer circuit.

### CROSS-REFERENCE TO RELATED APPLICATIONS

This application claims the priority of Korean Patent Application No. 10-2009-0087724 filed on Sep. 16, 2009, in the Korean Intellectual Property Office, the disclosure of which is incorporated herein by reference.

### BACKGROUND OF THE INVENTION

1. Field of the Invention

The present invention relates to multi-layer ceramic circuit boards, and more particularly, to a multi-layer ceramic circuit board on which a chip, such as a flip chip or a ball grid array (BGA) IC chip, which has bumps, is mounted, a method of manufacturing the same, and an electric device module using the same.

2. Description of the Related Art

Multi-layer ceramic circuit boards, such as low temperature cofired ceramic substrates, are widely used for boards for surface-mounted packages for active and passive elements. There is an increasing need to realize size reduction, high accuracy, high reliability, and thinning of these package devices.

In particular, since an integrated circuit (IC) to be mounted has the largest area, flip-chip or ball grid array (BGA) packages are generally used in order to reduce the size and height of the IC.

These flip-chip and BGA packaged IC chips generally include the under bump metallurgy (UBM) and conductive bumps such as solder balls, and are bonded to bonding pads provided in boars for packages. Here, bonding strength and reliability between the conductive bumps of the chips and the bonding pads on the boards for packages are very important.

As for packages for a flip chip or a BGA IC chip, conductive bumps, such as solder bumps, are formed on a UBM layer of the chip. The conductive bumps are two-dimensionally bonded to the surface of the bonding pads provided on a ceramic substrate, such as an LTCC board. However, this two-dimensional bonding structure is hard to ensure high bonding strength between the conductive bumps and the bonding pads.

In particular, a deterioration of bonding strength significantly reduces package reliability due to a difference in thermal expansion coefficients between the chip and the board. In order to increase the package reliability, an underfill process is further required to ensure high bonding strength by filling space between the chip and the board after the conductive bumps of the chip is bonded to the bonding pads of the board.

### SUMMARY OF THE INVENTION

An aspect of the present invention provides a multi-layer ceramic circuit board that can ensure high bonding strength by maximizing a contact area between a conductive bump and a bonding pad when mounting a flip chip or a BGA type IC.

An aspect of the present invention also provides a method of manufacturing a multi-layer ceramic circuit board that can ensure high bonding strength by maximizing a contact area between a conductive bump of a chip to be mounted on the surface and a bonding pad to be connected thereto.

An aspect of the present invention also provides an electronic device module that can ensure high bonding strength by maximizing a contact area between a conductive bump of a chip to be mounted on the surface and a bonding pad to be connected thereto, and can simplify a process by omitting an underfill process by reducing the height of a package.

According to an aspect of the present invention, there is provided a multi-layer ceramic circuit board including: a ceramic body having a plurality of ceramic green sheets stacked upon one another and an interlayer circuit having conductive vias and conductive patterns separately provided in the plurality of ceramic green sheets; a bump receiving portion provided in at least one surface ceramic green sheet adjacent to a surface of the plurality of ceramic green sheets, and having side walls inclined upward; and a bonding pad provided on the inclined side walls and a bottom surface of the bump receiving portion, and connected to the interlayer circuit.

The multi-layer ceramic circuit board may further include a catch pad provided on a top surface of the ceramic green sheet, providing the bottom surface of the bump receiving portion, among the plurality of ceramic green sheets at a position corresponding to the bump receiving portion.

The catch pad may have a larger area than the bottom surface of the bump receiving portion.

The bonding pad may include a first electrode layer provided on the inclined side walls of the bump receiving portion and a second electrode layer provided on a surface of the first electrode layer, and the catch pad or the interlayer circuit, exposed on the bottom surface of the bump receiving portion.

The first electrode layer may be formed of the same material as the interlayer circuit, and the second electrode layer may be a plated layer.

According to another aspect of the present invention, there is provided a method of manufacturing a multi-layer ceramic circuit board, the method including: forming at least one hole having side walls inclined upward in at least one first ceramic green sheet at a position corresponding to a bonding pad to be formed; forming a first electrode layer on the inclined side walls of the hole using conductive paste; forming conductive pads and conductive vias using conductive paste in a plurality of second ceramic green sheets in order to form an interlayer circuit; stacking the at least one first ceramic green sheet and the plurality of second ceramic green sheets while the at least one first ceramic green sheet forms a surface to thereby form a ceramic laminated body; and providing a bonding pad including the first electrode layer and a second electrode layer by forming the second electrode layer on the side walls and a bottom surface of the hole to be provided as a bump receiving portion after sinter the ceramic laminated body.

The forming of the conductive pads and the conductive vias in the plurality of second ceramic green sheets may include forming a catch pad using conductive paste on a top surface of the ceramic green sheet providing the bottom surface of the bump receiving portion among the plurality of second ceramic green sheets at a region thereof corresponding to the bump receiving portion.

The catch pad may have a larger area than the bottom surface of the bump receiving portion.

The providing of the bonding pad may include plating the first electrode layer formed on the side walls of the hole and the catch pad exposed on the bottom surface of the hole with the second electrode layer.

The conductive paste for forming the first electrode layer may be the same as conductive paste for forming the interlayer circuit.

According to another aspect of the present invention, there is provided an electronic device module including: a multi-layer ceramic circuit board having a ceramic body having a plurality of ceramic green sheets stacked upon one another and an interlayer circuit having conductive vias and conductive patterns separately provided in the plurality of ceramic green sheets, a plurality of bump receiving portions provided in at least one surface ceramic green sheet adjacent to a surface of the plurality of ceramic green sheets, and having side walls inclined upward; and a plurality of bonding pads separately provided on the individual inclined side walls and bottom surfaces of the plurality of bump receiving portions, and connected to the interlayer circuit; and an electronic device having a plurality of conductive bumps on a bottom surface thereof and mounted on the multi-layer ceramic circuit board so that the plurality of conductive bumps are separately located in the plurality of bump receiving portions.

The electronic device module may further include catch pads provided on a top surface of the ceramic green sheet, providing the bottom surfaces of the bump receiving portions, among the plurality of ceramic green sheets at regions thereof corresponding to the bump receiving portions.

The catch pads may have a large area of the bottom surfaces of the bump receiving portions.

Each of the bonding pads may include a first electrode layer provided on the inclined side walls of the bump receiving portion and a second electrode layer provided on a surface of the first electrode layer, and the catch pad or the interlayer circuit, exposed on the bottom surface of the bump receiving portion.

The first electrode layer may be formed of the same material as the interlayer circuit, and the second electrode layer may be a plated layer.

The conductive bumps of the electronic device may be separately connected to the individual bonding pads so that the conductive bumps make contact with the bonding pads located on the side walls and the bottom surfaces of the bump receiving portions.

The bottom surface of the electronic device may make contact with a top surface of the multi-layer ceramic circuit board.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating an electronic device module according to an exemplary embodiment of the present invention;

FIGS. 2A through 2C are cross-sectional views illustrating a multi-layer ceramic circuit board according to a specific embodiment of the present invention;

FIGS. 3A and 3B are cross-sectional views illustrating the process flow for manufacturing a surface ceramic green sheet of the multi-layer ceramic circuit board of FIG. 2;

FIGS. 4A through 4C are cross-sectional views illustrating the process flow for manufacturing an inner ceramic green sheet adjacent to a surface ceramic green sheet of the multi-layer ceramic circuit board of FIG. 2; and

FIGS. 5A through 5C are cross-sectional views illustrating the process flow for manufacturing a multi-layer ceramic circuit board using the surface ceramic green sheet of FIG. 3 and the inner ceramic green sheet of FIG. 4.

### DETAILED DESCRIPTION OF THE PREFERRED EMBODIMENT

Exemplary embodiments of the present invention will now be described in detail with reference to the accompanying drawings.

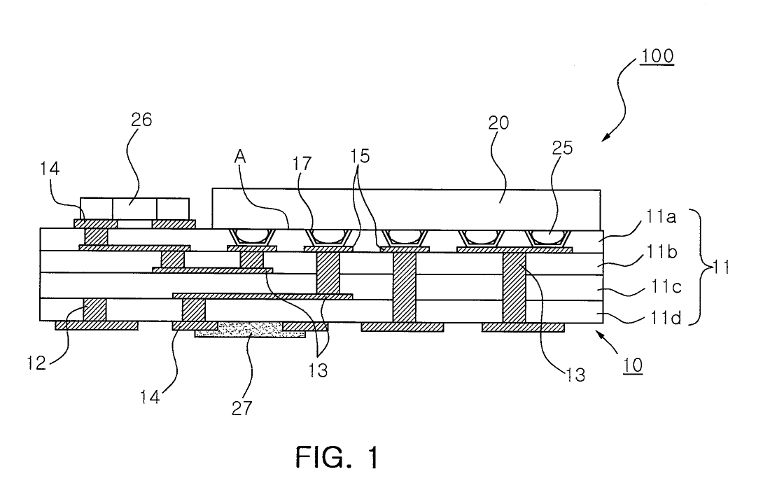

FIG. 1 is a cross-sectional view illustrating an electronic device module 100 according to an exemplary embodiment of the invention.

Referring to FIG. 1, an electronic device module 100 according to this embodiment includes a plurality of electronic devices 20, 26 and 27 and a multi-layer ceramic circuit board 10 having the plurality of electronic devices 20, 26 and 27 mounted thereon.

In this embodiment, in addition to the BGA type electronic device 20, the passive elements 26 and 27 may be further included. The BGA type electronic device 20 has a bottom surface on which a plurality of conductive bumps 25, such as solder balls, are formed. As shown in FIG. 1, the passive elements 26 and 27 may include the MLCC 26 mounted onto an top surface of the board 10 by surface-mount technology and the film type resistor 27 formed on a bottom surface of the board 10.

The multi-layer ceramic circuit board 10 includes a ceramic body 11 having a plurality of ceramic green sheets 11a to 11d stacked upon each other and an interlayer circuit board formed in the ceramic body 11. The interlayer circuit board may have conductive vias 12 and conductive patterns 13 individually formed in the plurality of ceramic green sheets 11a to 11d.

The multi-layer ceramic circuit board 10 according to this embodiment includes a plurality of bump receiving portions 16 that are formed in the surface ceramic green sheet 11a, and each have side walls inclined upward. A plurality of bonding pads 17 are individually formed on the inclined side walls and bottoms of the plurality of bump receiving portions 16. The bonding pads 17 are electrically connected to the interlayer circuit (conductive vias or conductive patterns).

Catch pads 15 may be further formed on a top surface of the ceramic green sheet 11b, which provides the bottom surfaces of the bump receiving portions 16, among the plurality of ceramic green sheets 11a to 11d at positions corresponding to the bump receiving portions 16. Each of the catch pads 15 may have a larger area than the bonding pad 17 located on the bottom surface of the bump receiving portion 16 in order to facilitate a connection between the bonding pad 17 and the interlayer circuit. Further, the catch pads 15 may have a larger diameter than the conductive vias 12 or may have a lager line width than the conductive patterns 13 to be connected to the bonding pads, thereby providing a stable connection between the bonding pads 17 and the interlayer circuit.

The BGA type electronic device 20 is mounted onto the top surface of the multi-layer ceramic circuit board 10 so that the conductive bumps 25 are individually located in the plurality of bump receiving portions 16. The conductive bumps 25 are separately connected to the individual bonding pads 17 of the multi-layer ceramic circuit board 10. In particular, since the bump receiving portions 16 according to this embodiment include the inclined side walls, the conductive bump 25 can be easily connected to both the side walls and the bottom surfaces of the bonding pads 17. Since the bonding pads may have larger contact areas than the conductive bump 25 as compared with two-dimensional pads 14 in the related art, thereby ensuring high bonding strength.

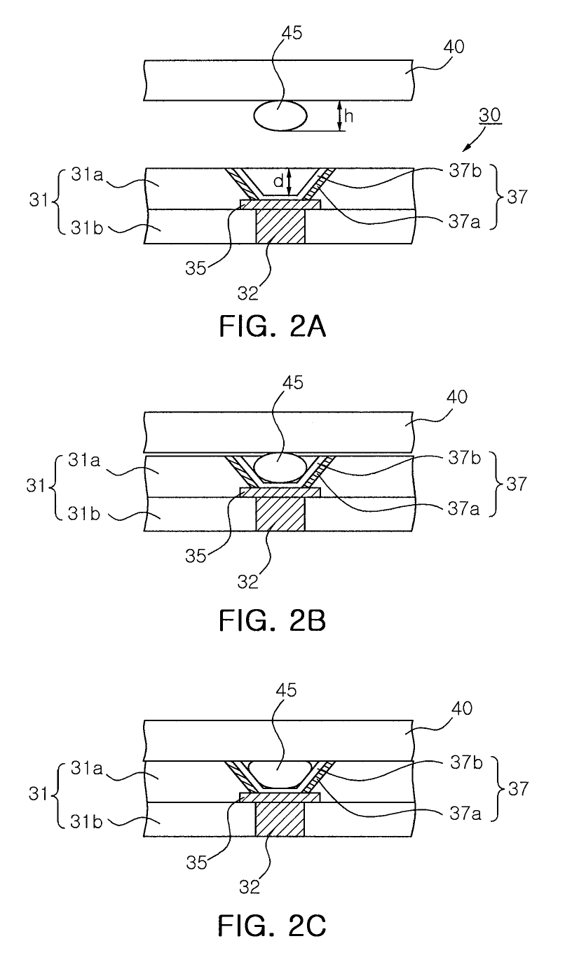

In addition, since the conductive bumps 25 of the BGA type electronic device 20 are received as deep as the bump receiving portions 16 within the bump receiving portions 16, the bottom surface of the BGA type electronic device 20 may be located adjacent to the top surface (that is, a mount surface) of the multi-layer ceramic circuit board 10. Like this embodiment, a bottom surface of the electronic device 20 may make contact with a top surface of the multi-layer ceramic circuit board 10. This will be described in detail with reference to FIG. 2.

Furthermore, when the bottom surface of the BGA type electronic device 20 makes contact with the top surface of the multi-layer ceramic circuit board 10 or there is little room therebetween, the underfill process can be omitted.

In this embodiment, the BGA type electronic device, which is similar to an IC chip, is exemplified. However, various kinds of flip chips having a bump structure similar to solder balls may be applied to this invention.

FIGS. 2A through 2C are cross-sectional views illustrating a multi-layer ceramic circuit board according to a specific embodiment of the invention.

Referring to FIG. 2A, a multi-layer ceramic circuit board 30 according to this embodiment includes a ceramic body 31 having a plurality of ceramic green sheets 31a and 31b stacked upon one another, and a conductive via 32 formed in the inner ceramic green sheet 31ba among the plurality of ceramic green sheets.

The multi-layer ceramic circuit board 30 includes a bump receiving portion 36 formed in the surface ceramic green sheet 31a among the plurality of ceramic green sheets. The bump receiving portion 36 has side walls inclined upward and a bottom surface. A bonding pad 37 is formed on the inclined sidewalls and the bottom surface of the bump receiving portion 36.

Like this embodiment, the bonding pad 37 may include a first electrode layer 37a formed on the inclined side walls of the bump receiving portions 36 and a second electrode layer 37b formed on the surface of the first electrode layer 37a and on a catch pad 35 exposed on the bottom surface of the bump receiving portion 36. In this case, the first electrode layer 37a is formed of the same material as the interlayer circuit, such as Ag. The second electrode layer 37b may be a layer plated with Ni, Au, or Ni/Au.

The bonding pad 37 is electrically connected to the conductive via 32 forming the interlayer circuit. Like this embodiment, the catch pad 35 has a relatively large area, thereby ensuring a stable connection between the conductive via 32 and the bonding pad 37.

As shown in FIG. 1, a bottom surface of an electronic device 40 may make contact with a top surface of the multi-layer ceramic circuit board 30. To this end, a depth d of the bump receiving portions 36 may be determined in consideration of a height h of a conductive bump 45. In consideration of an actual reflow process, the depth d of the bump receiving portions 36 may be slightly smaller than the height h of the conductive bump 45.

That is, as shown in FIG. 2B, the electronic device 40 is arranged on the multi-layer ceramic circuit board 30 so that the conductive bump 45 of the electronic device 40 is located in the bump receiving portion 36 of the multi-layer ceramic circuit board 30. The electronic device 40 may slightly come off the top surface of the multi-layer ceramic circuit board 30.

Then, as shown in FIG. 2C, through a high-temperature reflow process, the conductive bump 45 undergoing the reflow process is connected to the bonding pad 37 formed on the bottom surface and the side walls of the bump receiving portion 36, and may nearly contact a bottom surface of the electronic device 40 and the top surface of the multi-layer ceramic circuit board 30. Thus, the underfill process may be omitted.

Conditions on the height of the conductive bump 45 and the depth of the bump receiving portion 36 do not limit the invention. For example, in the operation of FIG. 2B, the height of the conductive bump 45 and the depth of the bump receiving portion 36 may be substantially the same as each other so that the electronic device nearly contacts the board.

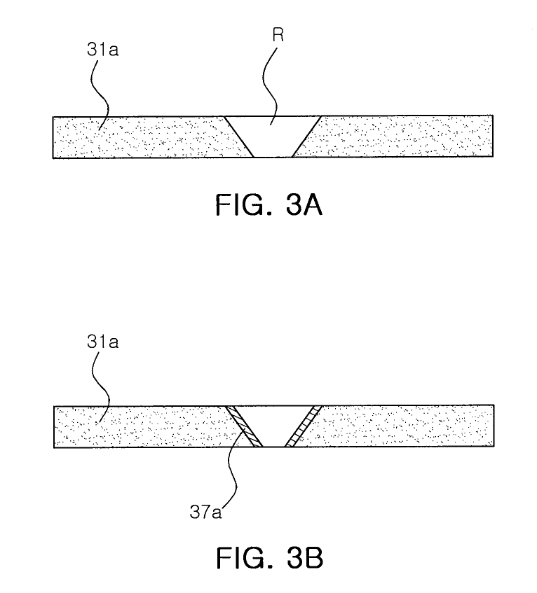

FIGS. 3A and 3B are cross-sectional views illustrating the process flow for manufacturing a surface ceramic green sheet of the multi-layer ceramic circuit board of FIG. 2.

As shown in FIG. 3A, at least one hole R that has side walls inclined upward is formed in the surface ceramic green sheet 31a at a position at which a bonding pad will be formed. In this process, laser irradiation may be performed to easily form desired incline side walls.

Then, as shown in FIG. 3B, the first electrode layer 37a is formed on the inclined side walls of the hole R using conductive paste. This process may be performed by a general through fill process. The conductive paste for the first electrode layer 37a may be formed of the same material as a different interlayer circuit, such as Ag paste.

In this embodiment, the process using one surface ceramic green sheet 31a is exemplified. However, top surfaces of two or more ceramic green sheets may be used. In this case, in order to obtain an inclined side wall structure, the ceramic green sheet, which is more adjacent to the surface than another ceramic green sheet, may have a larger diameter of the hole, thereby forming stepped side walls.

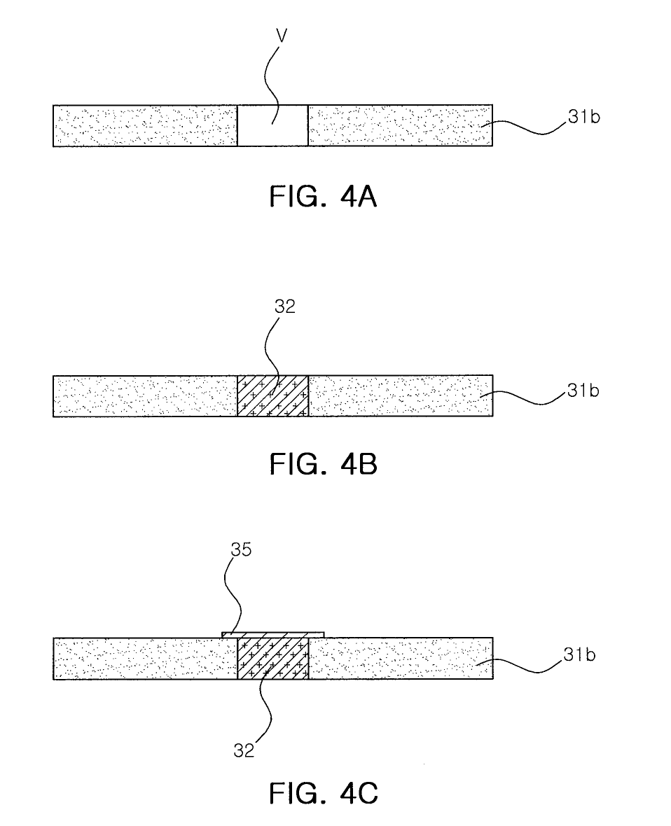

FIGS. 4A through 4C are cross-sectional views illustrating the process flow for manufacturing an inner ceramic green sheet adjacent to a surface ceramic green sheet of the multi-layer ceramic circuit board of FIG. 2.

As shown in FIG. 4A, a via V is formed in the inner ceramic green sheet 31b to form a conductive via.

Then, as shown in FIG. 4B, the conductive via 32 is formed in the inner ceramic green sheet 31b using conductive paste. The conductive via 32 may be formed through a known via fill process. The conductive paste, used in this process, may be a known material, such as Ag paste.

Then, as shown in FIG. 4C, the catch pad 35 may be formed on the inner ceramic green sheet 31b using conductive paste. This process may be performed using a general printing process. A conductive pattern (not shown) may be formed together using the same conductive paste.

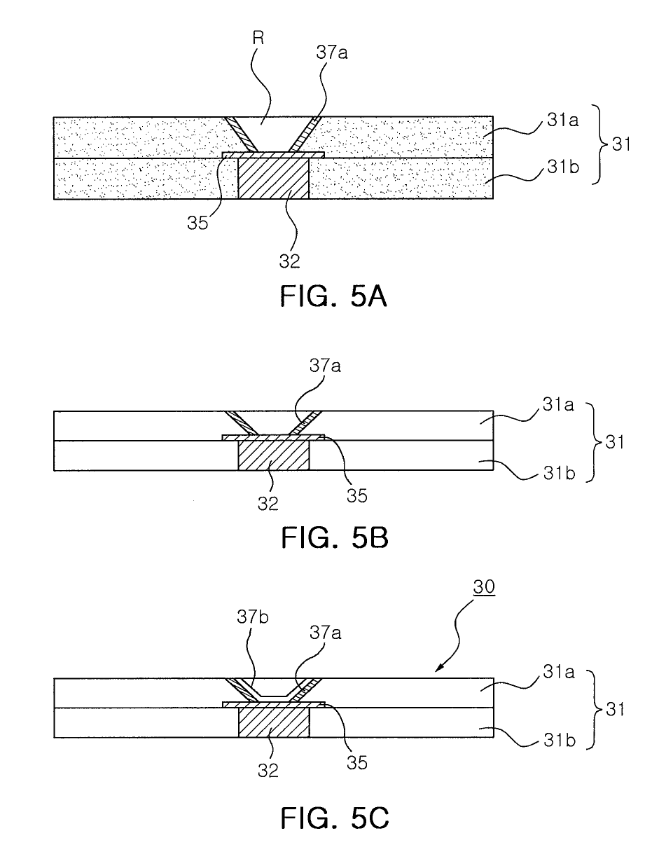

FIGS. 5A through 5C are cross-sectional views illustrating the process flow for manufacturing a multi-layer ceramic circuit board using the surface ceramic green sheet of FIG. 3 and the inner ceramic green sheet of FIG. 4.

As shown in FIG. 5A, the surface ceramic green sheet 31a and another ceramic green sheet 31b are staked upon one another while the surface ceramic green sheet 31a forms the surface, thereby forming the ceramic body 31.

Then, as shown in FIG. 5B, the ceramic body 31 is sintered. Here, the conductive via 32, the catch pad 35, and the first electrode layer 37a of the bonding pad, which are formed of the conductive paste, may be sintered together with the ceramic body 31.

Then, as shown in FIG. 5C, the second electrode layer 37b is formed on the side walls and the bottom surface of the hole R, which will be provided as the bump receiving portion 36, to thereby provide the bonding pad 37 including the first and second electrode layers 37a and 37b. The second electrode layer 37b may be a layer plated with Ni, Au, or Ni/Au.

As set forth above, according to exemplary embodiments of the invention, in a multi-layer ceramic circuit board for a package, when a chip, such as a flip chip or a BGA type IC, which has a conductive bump, is mounted onto a surface, the conductive bump of the chip is received in a bump receiving portion having a concave shape including a bonding pad, thereby ensuring high bonding strength. In particular, by forming inclined side walls of the bump receiving portion, a contact area between the bonding pad and the conductive bump can be effectively increased to thereby maximize bonding strength.

While the present invention has been shown and described in connection with the exemplary embodiments, it will be apparent to those skilled in the art that modifications and variations can be made without departing from the spirit and scope of the invention as defined by the appended claims.

What is claimed is:

1. A multi-layer ceramic circuit board comprising:
a ceramic body having a plurality of ceramic green sheets stacked upon one another and an interlayer circuit having conductive vias and conductive patterns separately provided in the plurality of ceramic green sheets;
a bump receiving portion provided in at least one surface ceramic green sheet adjacent to a surface of the plurality of ceramic green sheets, and having side walls inclined upward; and
a bonding pad provided on the inclined side walls and a bottom surface of the bump receiving portion, and connected to the interlayer circuit.

2. The multi-layer ceramic circuit board of claim 1, further comprising a catch pad provided on a top surface of the ceramic green sheet, providing the bottom surface of the bump receiving portion, among the plurality of ceramic green sheets at a position corresponding to the bump receiving portion.

3. The multi-layer ceramic circuit board of claim 2, wherein the catch pad has a larger area than the bottom surface of the bump receiving portion.

4. The multi-layer ceramic circuit board of claim 3, wherein the bonding pad comprises a first electrode layer provided on the inclined side walls of the bump receiving portion and a second electrode layer provided on a surface of the first electrode layer, and the catch pad or the interlayer circuit, exposed on the bottom surface of the bump receiving portion.

5. The multi-layer ceramic circuit board of claim 4, wherein the first electrode layer is formed of the same material as the interlayer circuit, and the second electrode layer is a plated layer.

6. A method of manufacturing a multi-layer ceramic circuit board, the method comprising:
forming at least one hole having side walls inclined upward in at least one first ceramic green sheet at a position corresponding to a bonding pad to be formed;
forming a first electrode layer on the inclined side walls of the hole using conductive paste;
forming conductive pads and conductive vias using conductive paste in a plurality of second ceramic green sheets in order to form an interlayer circuit;
stacking the at least one first ceramic green sheet and the plurality of second ceramic green sheets while the at least one first ceramic green sheet forms a surface to thereby form a ceramic laminated body; and
providing a bonding pad including the first electrode layer and a second electrode layer by forming the second electrode layer on the side walls and a bottom surface of the hole to be provided as a bump receiving portion after sinter the ceramic laminated body.

7. The method of claim 6, wherein the forming of the conductive pads and the conductive vias in the plurality of second ceramic green sheets comprises forming a catch pad using conductive paste on a top surface of the ceramic green sheet providing the bottom surface of the bump receiving portion among the plurality of second ceramic green sheets at a region thereof corresponding to the bump receiving portion.

8. The method of claim 7, wherein the catch pad has a larger area than the bottom surface of the bump receiving portion.

9. The method of claim 8, wherein the providing of the bonding pad comprises plating the first electrode layer formed on the side walls of the hole and the catch pad exposed on the bottom surface of the hole with the second electrode layer.

10. the method of claim 1, wherein the conductive paste for forming the first electrode layer is the same as conductive paste for forming the interlayer circuit.

11. An electronic device module comprising:
a multi-layer ceramic circuit board having a ceramic body having a plurality of ceramic green sheets stacked upon one another and an interlayer circuit having conductive vias and conductive patterns separately provided in the plurality of ceramic green sheets, a plurality of bump receiving portions provided in at least one surface ceramic green sheet adjacent to a surface of the plurality of ceramic green sheets, and having side walls inclined upward; and a plurality of bonding pads separately provided on the individual inclined side walls and bottom surfaces of the plurality of bump receiving portions, and connected to the interlayer circuit; and
an electronic device having a plurality of conductive bumps on a bottom surface thereof and mounted on the multi-layer ceramic circuit board so that the plurality of conductive bumps are separately located in the plurality of bump receiving portions.

12. The electronic device module of claim 11, further comprising catch pads provided on a top surface of the ceramic green sheet, providing the bottom surfaces of the bump receiving portions, among the plurality of ceramic green sheets at regions thereof corresponding to the bump receiving portions.

13. The electronic device module of claim 12, wherein the catch pads may have a large area of the bottom surfaces of the bump receiving portions.

14. The electronic device module of claim 13, wherein each of the bonding pads comprises a first electrode layer provided on the inclined side walls of the bump receiving portion and a second electrode layer provided on a surface of the first electrode layer, and the catch pad or the interlayer circuit, exposed on the bottom surface of the bump receiving portion.

15. The electronic device module of claim 14, wherein the first electrode layer is formed of the same material as the interlayer circuit, and the second electrode layer is a plated layer.

16. The electrode device module of claim 11, wherein the conductive bumps of the electronic device are separately connected to the individual bonding pads so that the conductive bumps make contact with the bonding pads located on the side walls and the bottom surfaces of the bump receiving portions.

17. The electrode device module of claim 16, wherein the bottom surface of the electronic device makes contact with a top surface of the multi-layer ceramic circuit board.
